(19) United States
(12) Patent Application Publication
(10) Pub. No.: US 2012/0050190 A1
(43) Pub. Date: Mar. 1, 2012

(54) DISPLAY APPARATUS

(75) Inventors: Chih-Chang Lai, Taichung City (TW); Ching-Fu Hsu, Taichung City (TW)

(73) Assignees: WINTEK CORPORATION, Taichung City (TW); WINTEK TECHNOLOGY(H.K) LTD., Dongguan (CN)

(21) Appl. No.: 13/046,704

(22) Filed: Mar. 12, 2011

(30) Foreign Application Priority Data
Mar. 16, 2010 (TW) 99107630

(51) Int. Cl. G06F 3/041; H05K 1/14; H05K 7/00

(52) U.S. Cl. 345/173; 361/728; 361/736

(57) ABSTRACT

A display apparatus including a display module and a protection structure is provided. The display module has an image display region and a trace disposing region surrounding the image display region. The protection structure is disposed on the display module and includes a cover, a first electrode layer, a substrate, a second electrode layer and a display medium layer. The first electrode layer is disposed on the cover and the location of the first electrode layer at least shields the trace disposing region. The substrate is disposed between the cover and the display module. The second electrode layer is disposed on the substrate corresponding to the first electrode layer. The location of the second electrode layer at least shields the trace disposing region. The display medium layer is disposed between the first electrode layer and the second electrode layer, wherein the display medium layer substantially surrounds the image display region.

### CROSS-REFERENCE TO RELATED APPLICATION

This application claims the priority benefit of Taiwan application serial no. 99107630, filed Mar. 16, 2010. The entirety of the above-mentioned patent application is hereby incorporated by reference herein and made a part of this specification.

### BACKGROUND

1. Field of the Invention

The invention relates to a display apparatus. Particularly, the invention relates to a display apparatus capable of arbitrarily changing a color of a border.

2. Description of Related Art

A conventional touch display apparatus includes a display panel, a touch panel disposed on the display panel and a transparent cover disposed on the touch panel, where the transparent cover is used to protect the touch panel and the display panel there below. Signals generated when a user operates the touch display panel are transmitted to a touch control chip on a printed circuit board, and the touch control chip analyses the received signals to determine a position of the touch display panel where the user touches.

In order to transmit the signals, trace regions configured with a plurality of wires are disposed at peripheries of the touch panel and the display panel. Moreover, in order to protect the touch panel and the display panel, a cover is generally added to the outermost side of the apparatus. If the trace regions are exposed, an overall appearance of the apparatus is influenced, so that a black ink layer is generally disposed on the cover at a position corresponding to the trace regions to shield the wires. Namely, a central region of the cover (corresponding to an image display region of the display panel) has a transparent design, and the surrounding region of the cover (corresponding to the trace position, i.e. the border of the touch display apparatus) presents a dark color or has an opaque design.

However, the color of the border set by the manufacturer does not necessarily meet the needs of the user. Moreover, the user cannot arbitrarily change the color of the border according to his preference. In other words, the conventional design cannot satisfy the demands of diversity and flexibility.

### SUMMARY OF THE INVENTION

The invention is directed to a display apparatus, which can arbitrarily changes a color of a border thereof according to a demand of a user.

The invention provides a display apparatus including a display module and a protection structure. The display module has an image display region and a trace disposing region surrounding the image display region. The protection structure is disposed on the display module and includes a cover, a first electrode layer, a substrate, a second electrode layer and a display medium layer. The first electrode layer is disposed on the cover and a location of the first electrode layer at least shields the trace disposing region. The substrate is disposed between the cover and the display module. The second electrode layer is disposed on the substrate and is located opposite to the first electrode layer. A location of the second electrode layer at least shields the trace disposing region. The display medium layer is disposed between the first electrode layer and the second electrode layer, where the display medium layer substantially surrounds the image display region.

According to the above descriptions, the first electrode layer, the second electrode layer and the display medium layer clamped between the two electrode layers are disposed on the cover at a position corresponding to the trace disposing region, where the display medium layer may display different gray levels under control of the first electrode layer and the second electrode layer. In this way, the display apparatus may have a function of arbitrarily changing a color of the border. Particularly, in collaboration with a color filter layer, the border may have a plurality of color variations. Therefore, the display apparatus of the invention may have a flexible and colourful border design.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a display apparatus according to an embodiment of the present invention.

FIG. 2 is a cross-sectional view of a display apparatus according to another embodiment of the present invention.

FIG. 3 is a cross-sectional view of a display apparatus according to another embodiment of the present invention.

FIG. 4 is a three-dimensional view of a display apparatus according to an embodiment of the present invention.

FIGS. 5-8 are cross-sectional views illustrating different types of protection structure according to embodiments of the present application.

### DETAILED DESCRIPTION OF DISCLOSED EMBODIMENTS

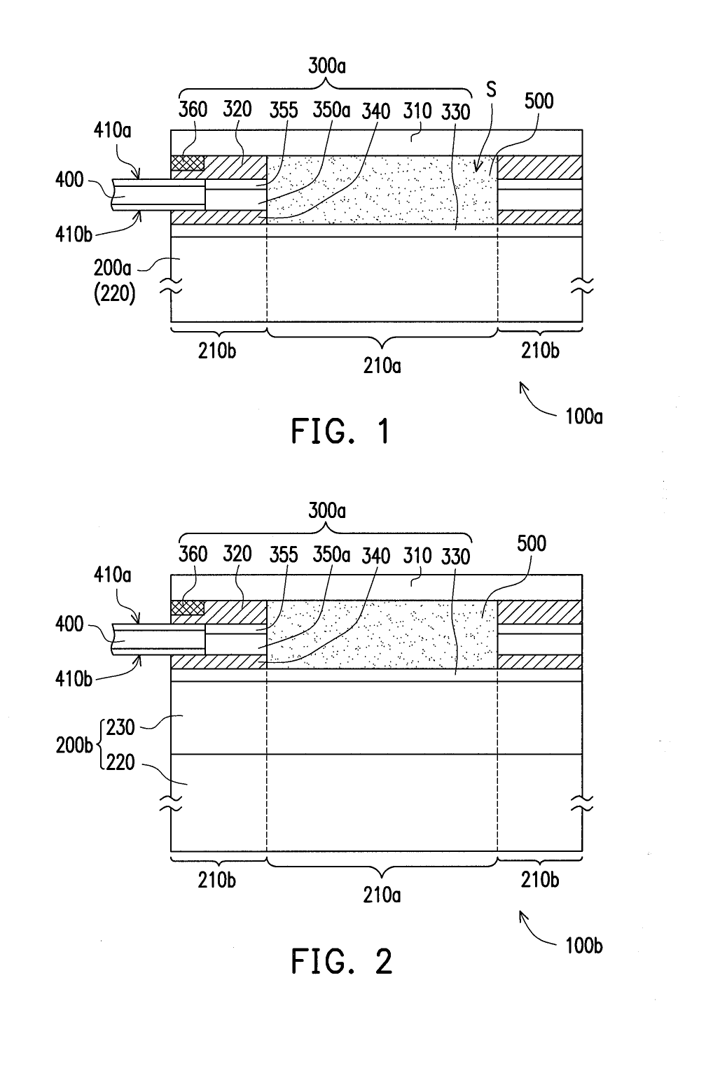

FIG. 1 is a cross-sectional view of a display apparatus according to an embodiment of the invention. Referring to FIG. 1, in the present embodiment, the display apparatus 100a includes a display module 200a and a protection structure 300a. The display module 200a has an image display region 210a and a trace disposing region 210b surrounding the image display region 210a. In the present embodiment, the display module 200a is, for example, a flat display panel 220, where the flat display panel 220 is, for example, a liquid crystal display (LCD) panel, an amorphous silicon LCD panel, a low temperature poly-silicon LCD panel, an organic electro-luminescence display panel, a plasma display panel, an electronic paper display panel, or an electro wetting display panel, though the invention is not limited thereto.

The protection structure 300a is disposed on the display module 200a and includes a cover 310, a first electrode layer 320, a substrate 330, a second electrode layer 340 and a display medium layer 350a. In detail, the first electrode layer 320 is disposed on the cover 310 and a location of the first electrode layer 320 at least shields the trace disposing region 210b of the display module 200a. The substrate 330 is disposed between the cover 310 and the display module 200a. The second electrode layer 340 is disposed on the substrate 330 and the second electrode 340 is disposed opposite to the first electrode layer 320. A location of the second electrode layer 340 at least shields the trace disposing region 210b of the display module 200a. The display medium layer 350a is disposed between the first electrode layer 320 and the second electrode layer 340, and the display medium layer 350a substantially surrounds the image display region 210a of the display module 200a. It should be noticed that a location of the display medium layer 350a is at least equal to or slightly greater than a width of the trace disposing region 210b. Namely, the location of the display medium layer 350a completely shields the trace disposing region 210b.

In the present embodiment, a material of the cover 310 is glass or plastic, which is used to guide external light into the protection structure 300a. The substrate 330 is, for example, a flexible substrate, and the display medium layer 350a is, for example, a display ink layer. A material of the second electrode layer 340 is, for example, a reflective conductive material, which is used to reflect the light passing through the cover 310 to external of the cover 310. The protection structure 300a of the present embodiment can use the external light reflected by the second electrode layer 340 of the protection structure 300a as a main light source. Namely, the second electrode layer 340 is made of the reflective conductive material. However, in other embodiments, the second electrode layer 340 can also be a transparent layer, and the protection structure 300a may further include a reflection layer disposed between the substrate 330 and the second electrode layer 340. How the protection structure 300a reflect the external light is not limited by the invention.

Generally, the substrate 330, the second electrode layer 340 on the substrate 330 and the display medium layer 350a are integrally packaged to form an electronic paper display (EPD) film. The EPD film may also include an insulating layer (not shown) located between the second electrode layer 340 and the display medium layer 350a and an adhesive layer 355 used for adhering the first electrode layer 320. It should be noticed that arrangement and patterns of the film layers in the EPD film are diversified, and the structure design of FIG. 1 is only an example, which is not used to limit the invention. Particularly, since the substrate 330 is a flexible substrate, an electrophoresis film formed after the packaging can be arbitrarily cut into the required shape so as to fit the trace disposing region 210b of the display module 200a.

Moreover, the display apparatus 100a of the present embodiment further includes a flexible circuit board 400 and an optical adhesive 500. The flexible circuit board 400 is disposed between the cover 310 and the substrate 330, and has two connecting surfaces 410a and 410b opposite to each other for respectively connecting the first electrode layer 320 and the second electrode layer 340. Namely, the flexible circuit board 400 is a double-side circuit board. The optical adhesive 500 is filled in a space S encircled by the cover 310, the substrate 330 and the display medium layer 350a. By using the optical adhesive 500, a display quality of the display module 200a is not influenced by the space S.

Particularly, the protection structure 300a of the present embodiment may further include a light shielding pattern 360, where the light shielding pattern 360 is disposed on the cover 310, and is at least located between the flexible circuit board 400 and the cover 310. The light shielding pattern 360 can be used to shield a configuration position of the flexible circuit board 400, which avails beautifying an appearance of the protection structure 300a. The light shielding pattern 360 may present a special shape or a mark in an activating state through a special design. Moreover, the light shielding pattern 360 may also present a frame shape in the activating state. It should be noticed that a width of the light shielding pattern 360 in a direction parallel to the cover 310 is applicable as long as the light shielding pattern 360 can shield the flexible circuit board 400.

When an electric field is applied to the protection structure 300a, the display medium layer 350a located between the first electrode layer 320 and the second electrode layer 340 may have color variations, for example, produce a black and white variation (i.e. a gray level variation). In this way, the region of the protection structure 300a corresponding to the trace disposing region 210b of the display module 200a may have an appearance design of color diversity (i.e. the gray level). Therefore, the display apparatus 100a can arbitrarily change the color displayed by the region of the protection structure 300a (i.e. the border of the display apparatus 100a) corresponding to the trace disposing region 210b of the display module 200a.

It should be noticed that a pattern and a position of the display module 200a are not limited by the invention, and although the display module 200a of the embodiment is implemented by a flat display panel 220, and is disposed adjacent to the substrate 330 of the protection structure 300a, in other embodiments, referring to FIG. 2, a display module 200b of a display apparatus 100b can also be composed of a touch device 230, for example, a touch panel, and the flat display panel 220, where the touch device 230 (for example, the touch panel) is disposed between the flat display panel 220 and the substrate 330.

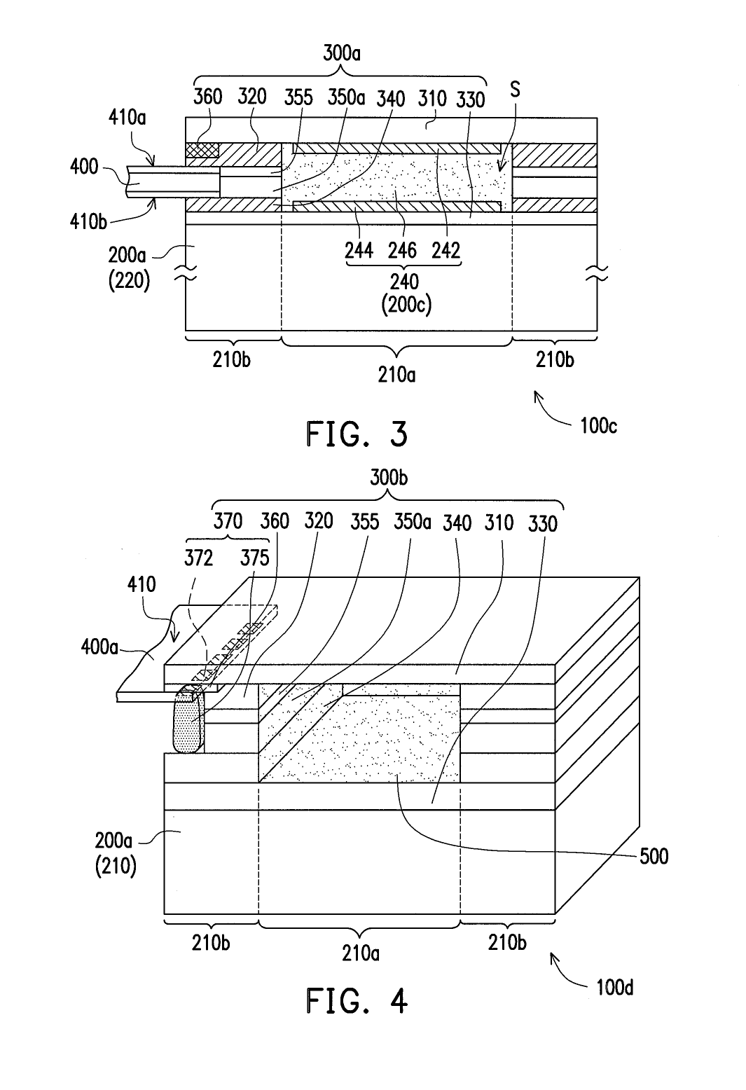

Alternatively, referring to FIG. 3, a display apparatus 100c further includes a touch device 240, where the touch device 240 is, for example, a touch sensing electrode. The touch device 240 is disposed in the space S encircled by the cover 310, the substrate 330 and the display medium layer 350a. Namely, the touch device 240 is disposed in the space S other than the optical adhesive 500 (as shown in FIG. 1). For example, the touch device 240 includes a third electrode layer 242, a fourth electrode layer 244 and a medium layer 246 located between the third electrode layer 242 and the fourth electrode layer 244. The third electrode layer 242 is disposed on the cover 310, and the fourth electrode layer 244 is disposed on the substrate 330 and is located opposite to the third electrode layer 242. Moreover, the touch device 240 can also be composed of coplanar electrode strings, and the touch device 240 illustrated in FIG. 3 is only an example, which is not used to limit the structure of the touch device 240 of the invention.

Moreover, a pattern of the flexible circuit board 400 is not limited by the invention, although the flexible circuit board 400 of the embodiment is implemented by a double-side circuit board, in other embodiments, referring to FIG. 4, a flexible circuit board 400a of a display apparatus 100d can also be a single-side circuit board, namely, the flexible circuit board 400a has a single connecting surface 410. In detail, a protection structure 300b of the display apparatus 100d further includes a conductive connection structure 370, which is disposed between the first electrode layer 320 and the cover 310. The first electrode layer 320 can be connected to the connecting surface 410 of the flexible circuit board 400a closed to the cover 310 through the conductive connection structure 370. In the present embodiment, the conductive connection structure 370 may include a plurality of pad pins 372 disposed on the cover 310 and a vertical conductive member disposed between a part of the pad pins 372 and the second electrode layer 340, where the vertical conductive member can be a silver adhesive 375 or other anisotropic conductive members. The second electrode layer 340 can be electrically connected to a part of the pad pins 372 through the silver adhesive 375. Therefore, signals output from the flexible circuit board 400a can be transmitted to the second electrode layer 340 to achieve color variation of the display medium layer 350a. The aforementioned electrical connection method is only an example, which is not limited by the invention.

Different embodiments are provided below to describe protection structures 300c-300f. It should be noticed that the reference numerals and a part of the contents of the aforementioned embodiment are also used in the following embodiments, and like reference numerals in the following embodiments denote like elements, and thus descriptions of the same technical contents are omitted. Moreover, the aforementioned embodiment can be referred for the omitted part, so that detailed descriptions thereof are not repeated.

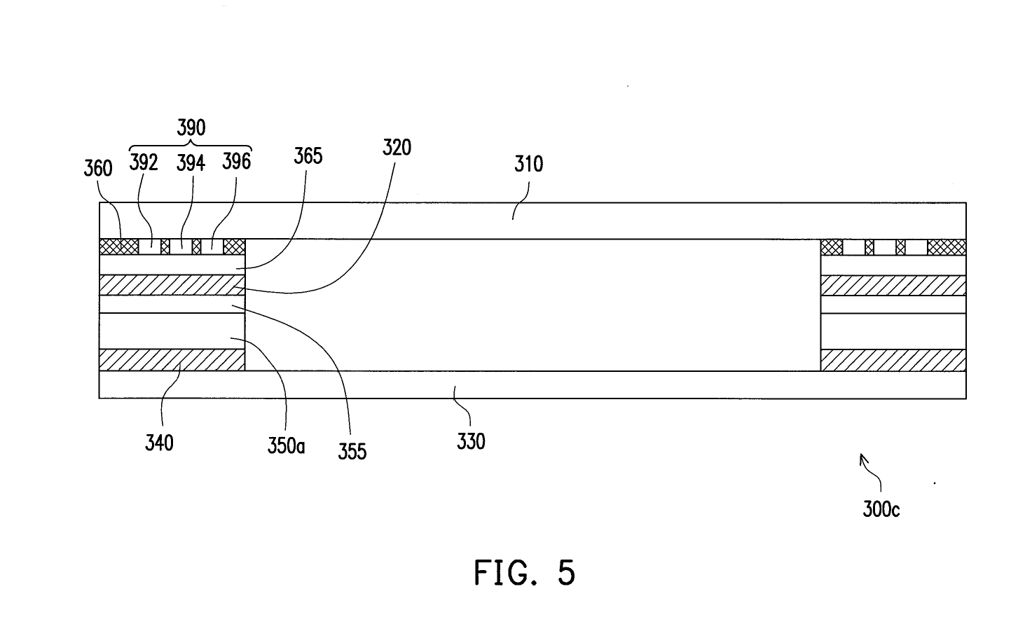

FIG. 5 is a cross-sectional view of a protection structure according to an embodiment of the invention. Referring to FIG. 1 and FIG. 5, the protection structure 300c of the present embodiment is similar to the protection structure 300a of FIG. 1, and a difference there between is that the protection structure 300c further includes a color filter layer 390 and a protection layer 365. In detail, the color filter layer 390 is disposed on the cover 310 and is located between the first electrode layer 320 and the cover 310. The color filter layer 390 is composed of a plurality of red filter patterns 392, a plurality of green filter patterns 394 and a plurality of blue filter patterns 396. The protection layer 365 is located between the first electrode layer 320 and the color filter layer 390, for isolating the first electrode layer 320 and the color filter layer 390.

Since the protection structure 300c of the present embodiment has the color filter layer 390, when the display medium layer 350a displays a specific gray level, different color variations can be achieved in collaboration with the color filter layer 390, for example, reflection variations of three primary colours of red, green and blue can be achieved. In this way, the region of the protection structure 300c corresponding to the trace disposing region 210b (referring to FIG. 1) of the display module 200a (referring to FIG. 1) has an appearance design of color diversity (colourful), so that the color presented by the border can be arbitrarily changed to satisfy the demand of the user.

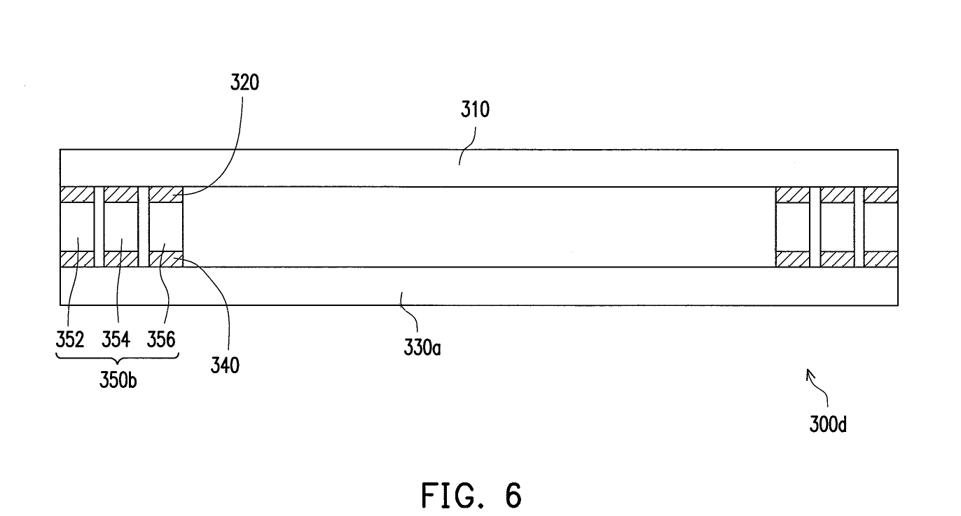

FIG. 6 is a cross-sectional view of a protection structure according to an embodiment of the invention. Referring to FIG. 1 and FIG. 6, the protection structure 300d of the present embodiment is similar to the protection structure 300a of FIG. 1, and a difference there between is that a display medium layer 350b of the protection structure 300d is a cholesteric liquid crystal layer, and a material of a substrate 330a is, for example, glass. In detail, in the present embodiment, the display medium layer 350b (i.e. the cholesteric liquid crystal layer) is composed of a red liquid crystal material layer 352, a green liquid crystal material layer 354 and a blue liquid crystal material layer 356. The red liquid crystal material layer 352, the green liquid crystal material layer 354 and the blue liquid crystal material layer 356 are arranged in parallel between the first electrode layer 320 and the second electrode layer 340.

Certainly, in other embodiments that are not illustrated, the red liquid crystal material layer 352, the green liquid crystal material layer 354 and the blue liquid crystal material layer 356 can also be stacked between the first electrode layer 320 and the second electrode layer 340. The structure design of FIG. 6 is only an example, and the invention is not limited thereto. Since the display medium layer 350b of the present embodiment is the cholesteric liquid crystal layer, and the cholesteric liquid crystal layer has a bistable characteristic, and a suitable driving voltage is supplied only when the image is updated, an advantage of low power consumption is achieved.

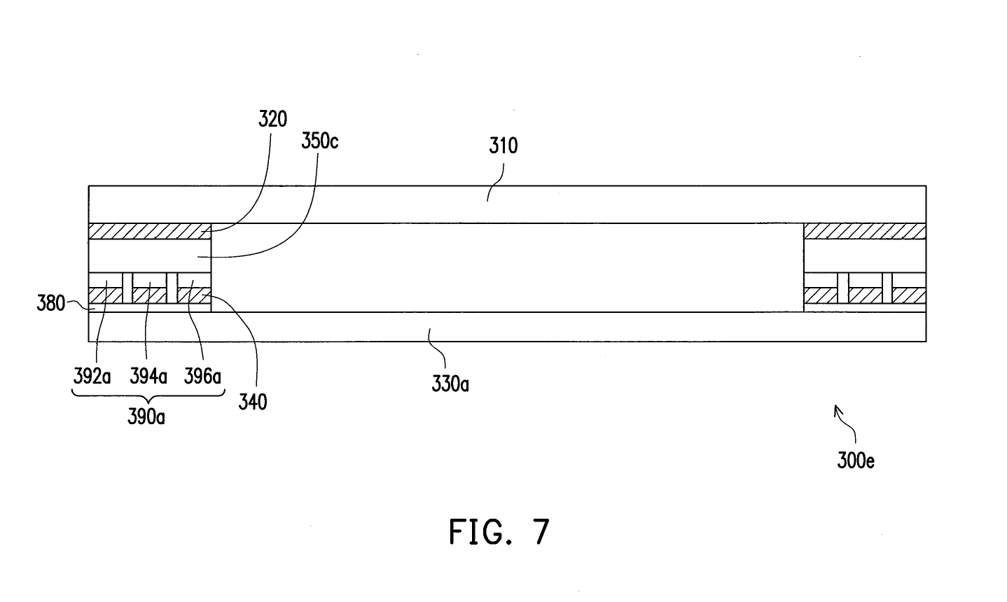

FIG. 7 is a cross-sectional view of a protection structure according to an embodiment of the invention. Referring to FIG. 1 and FIG. 7, the protection structure 300e of the present embodiment is similar to the protection structure 300a of FIG. 1, and a difference there between is that the protection structure 300e further includes a reflection layer 380 and a color filter layer 390a. Moreover, the display medium layer 350c is a twist nematic liquid crystal layer, and the second electrode layer 340 is a conductive material, for example, indium-doped tin oxide (ITO) or indium zinc oxide (IZO). A material of the substrate 330a is glass.

In detail, the reflection layer 380 is disposed between the second electrode layer 340 and the substrate 330a, and the reflection layer 380 exposes the image display region 210a (referring to FIG. 1). The protection structure 300e of the present embodiment can use the external light reflected by the reflection layer 380 as a main light source. The color filter layer 390a is disposed between the display medium layer 350c and the second electrode layer 340, where the color filter layer 390a is composed of a plurality of red filter patterns 392a, a plurality of green filter patterns 394a and a plurality of blue filter patterns 396a. In another embodiment, the second electrode layer 340 can be a reflective electrode layer, and the reflection layer 380 is omitted.

Since the display medium layer 350c is the twist nematic liquid crystal layer, an external electric field can be applied to control the twist of the display medium layer 350c to present a bright or a dark effect. Moreover, since the protection structure 300e has the color filter layer 390a, when an electric field variation is generated between the first electrode layer 320 and the second electrode layer 340, the gray level displayed by the display medium layer 350c may have different color variations in collaboration with the color filter layer 390a, for example, reflection variations of three primary colours of red, green and blue can be achieved. In other words, the color presented by the border can be arbitrarily changed to satisfy the demand of the user.

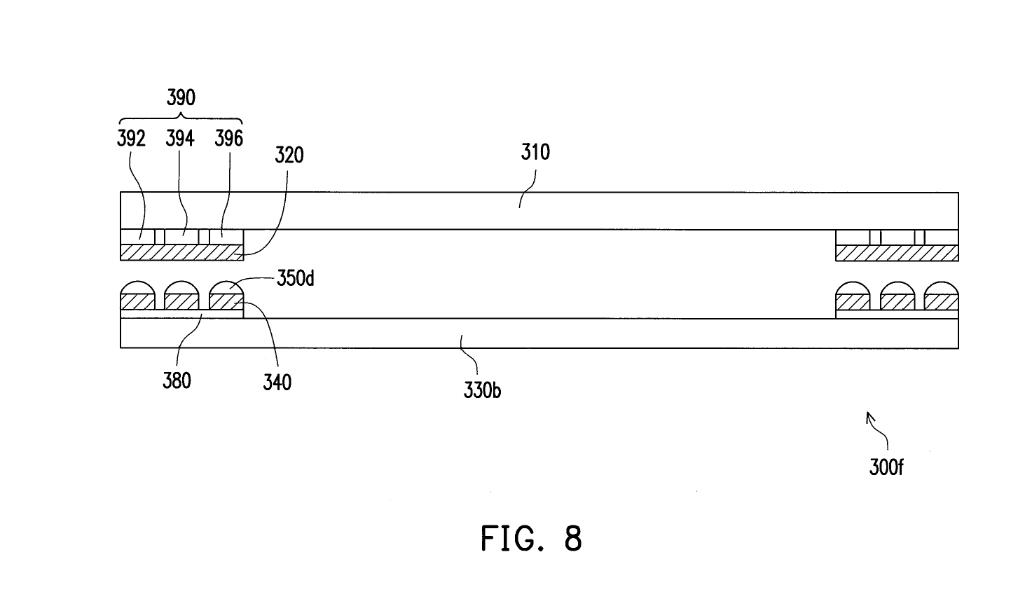

FIG. 8 is a cross-sectional view of a protection structure according to another embodiment of the invention. Referring to FIG. 1 and FIG. 8, the protection structure 300f of the present embodiment is similar to the protection structure 300a of FIG. 1, and a difference there between is that the protection structure 300f further includes a color filter layer 390 and a reflection layer 380. Moreover, the display medium layer 350d is an electro wetting display medium, which is composed of a hydrophobic mobile medium (not shown) and a hydrophilic mobile medium (not shown). A material of the second electrode layer 340 is, for example, indium-doped tin oxide (ITO) or indium zinc oxide (IZO).

In detail, the color filter layer 390 is disposed on the cover 310, and is located between the first electrode 320 and the cover 310, and the color filter layer 390 is composed of a plurality of red filter patterns 392, a plurality of green filter patterns 394 and a plurality of blue filter patterns 396. The reflection layer 380 is disposed between the second electrode layer 340 and the substrate 330b, and exposes the image display region 210a (referring to FIG. 1). The protection structure 300f of the present embodiment can use the external light reflected by the reflection layer 380 as a main light source.

Since the display medium layer 350d is the electro wetting display medium, when an electric field is applied to the protection structure 300f, a contact surface of the hydrophobic mobile medium (not shown) and the hydrophilic mobile medium (not shown) is changed as the electric field between the first electrode layer 320 and the second electrode layer 340 is varied, so as to present colours of different gray levels. Moreover, the display medium layer 350d and the color filter layer 390 may have color variations due to variation of the electric field, for example, produce reflection variations of three primary colours of red, green and blue. In other words, the border of the present embodiment has an appearance design of color diversity (colourful), so as to satisfy the demand of the user.

Certainly, the above protection structures 300a-300f are only examples, and those skilled in the art can modify the elements therein according to an actual design requirement with reference of the descriptions of the aforementioned embodiments, so as to achieve required technical effects. As long as the first electrode layer 320, the second electrode layer 340 and the display medium layers 350a-350d clamped between the two electrode layers are disposed on the cover 310 of the display apparatus 100a-100d at a position corresponding to the trace disposing region 210b, and the display medium layers 350a-350d can display different colours due to the electric field variations, it is considered to be within the scope of the invention.

In summary, the first electrode layer, the second electrode layer and the display medium layer clamped between the two electrode layers are disposed on the cover at a position corresponding to the trace disposing region, where the display medium layer may display different gray levels under control of the first electrode layer and the second electrode layer. In this way, the display apparatus may have a function of arbitrarily changing a color of the border. Particularly, in collaboration with a color filter layer, the border may have a plurality of color variations. Therefore, the display apparatus of the invention may have a flexible and colourful border design.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A display apparatus, comprising:
a display module, having an image display region and a trace disposing region surrounding the image display region; and
a protection structure, disposed on the display module, and comprising:
a cover;
a first electrode layer, disposed on the cover, and a location of the first electrode layer at least shielding the trace disposing region;
a substrate, disposed between the cover and the display module;
a second electrode layer, disposed on the substrate and located opposite to the first electrode layer, and a location of the second electrode layer at least shielding the trace disposing region; and
a display medium layer, disposed between the first electrode layer and the second electrode layer, wherein the display medium layer substantially surrounds the image display region.

2. The display apparatus as claimed in claim 1, wherein the display module comprises a display panel.

3. The display apparatus as claimed in claim 2, wherein the display module further comprises a touch device, and the touch device is disposed between the display panel and the substrate or disposed in a space encircled by the cover, the substrate and the display medium layer.

4. The display apparatus as claimed in claim 1, further comprising a flexible circuit board disposed between the cover and the substrate, and electrically connected to the first electrode layer and the second electrode layer, wherein the protection structure further comprises a light shielding pattern disposed on the cover and at least located between the flexible circuit board and the cover.

5. The display apparatus as claimed in claim 4, wherein the flexible circuit board is a double-side circuit board or a single-side circuit board.

6. The display apparatus as claimed in claim 1, wherein a material of the cover comprises glass or plastic.

7. The display apparatus as claimed in claim 1, further comprising an optical adhesive filled in a space encircled by the cover, the substrate and the display medium layer.

8. The display apparatus as claimed in claim 1, wherein a material of the second electrode layer is a reflective conductive material.

9. The display apparatus as claimed in claim 1, wherein the protection structure further comprises a reflection layer disposed between the second electrode layer and the substrate, and the reflection layer exposes the image display region.

10. The display apparatus as claimed in claim 1, wherein the protection structure further comprises a color filter layer disposed between the first electrode layer and the cover.
